(19) United States
(12) Patent Application Publication
(10) Pub. No.: US 2019/0013292 A1
(43) Pub. Date: Jan. 10, 2019

(54) METHODS FOR WIRE BONDING AND TESTING AND FLASH MEMORIES FABRICATED BY THE SAME

(71) Applicant: Silicon Motion, Inc., Jhubei City (TW)

(72) Inventors: Shu-Ying HUANG, Hsinchu City (TW); Te-Wei CHEN, Zhubei City (TW); Hsiu-Yuan CHEN, Zhubei City (TW)

(21) Appl. No.: 15/869,816

(22) Filed: Jan. 12, 2018

(30) Foreign Application Priority Data
Jul. 5, 2017 (TW) 106122504

(51) Int. Cl. H01L 23/00; H01L 25/00; H01L 25/065; H01L 21/66

(52) U.S. Cl. CPC H01L 24/75; H01L 25/50; H01L 25/0652; H01L 24/85; H01L 24/48; H01L 22/14; H01L 2924/14511; H01L 2225/06562; H01L 2224/859; H01L 2224/48227; H01L 2224/752; H01L 2224/759; H01L 2924/30205; H01L 2225/0651

(57) ABSTRACT

The invention introduces a method for wire bonding and testing, performed by wire-bonding equipment, including at least the following steps: providing a substrate and dies, where the substrate has exposed fingers and each die has exposed pads; controlling a motor to hold the substrate by a metal frame, where all the exposed fingers are floating from the metal frame to avoid ESD (electrostatic discharge) fail; and performing a wire bonding to make interconnections between the pads on the dies and the fingers on the substrate to fabricate a semi-finished flash-memory product.

### CROSS REFERENCE TO RELATED APPLICATIONS

This Application claims priority of Taiwan Patent Application No. 106122504, filed on Jul. 5, 2017, the entirety of which is incorporated by reference herein.

### BACKGROUND

### Technical Field

The present invention relates to flash memory, and in particular to methods for wire bonding and testing and flash memories fabricated by the same.

### Description of the Related Art

Flash memory devices typically include NOR flash devices and NAND flash devices. NOR flash devices are random access—a host accessing a NOR flash device can provide the device any address on its address pins and immediately retrieve data stored in that address on the device's data pins. NAND flash devices, on the other hand, are not random access but serial access. It is not possible for NOR to access any random address in the way described above. Instead, the host has to write into the device a sequence of bytes which identifies both the type of command requested (e.g. read, write, erase, etc.) and the address to be used for that command. The address identifies a page (the smallest chunk of flash memory that can be written in a single operation) or a block (the smallest chunk of flash memory that can be erased in a single operation), and not a single byte or word. In reality, the NAND flash device always reads from the memory cells and writes to the memory cells complete pages. After a page of data is read from the array into a buffer inside the device, the host can access the data bytes or words one by one by serially clocking them out using a strobe signal.

Wire bonding is the method of making interconnections between ICs (integrated circuits) and a PCB (printed circuit board) during semiconductor device fabrication. To improve the performance, a flash memory device typically includes dies holding a controller and storage sub-units, and wires being produced to connect dies. However, a bad wire bonding and testing method may introduce ESD (Electrostatic Discharge) fail to damage one or more of the controller and storage sub-units. Accordingly, what is needed are methods for wire bonding and testing and flash memories fabricated by the methods to address the aforementioned problems.

### BRIEF SUMMARY

An embodiment of the invention introduces a method for wire bonding and testing, performed by wire-bonding equipment, including at least the following steps: providing a substrate and dies, where the substrate has exposed fingers and each die has exposed pads; controlling a motor to hold the substrate by a metal frame, where all the exposed fingers are floating from the metal frame to avoid ESD (electrostatic discharge) fail; and performing a wire bonding to make interconnections between the pads on the dies and the fingers on the substrate to fabricate a semi-finished flash-memory product.

An embodiment of the invention introduces a flash memory including at least a substrate, a first die disposed on the substrate, and second dies disposed on the substrate. The substrate has exposed fingers, in which no metal line is formed to connect one of the exposed fingers to an edge of the substrate to avoid ESD (electrostatic discharge) fail when a wire bonding is performed. The first die comprises IC (Integrated Circuit) of a controller, and exposed pads. Each second die comprises IC of a storage sub-unit, and exposed pads.

A detailed description is given in the following embodiments with reference to the accompanying drawings.

### BRIEF DESCRIPTION OF THE DRAWINGS

The present invention can be fully understood by reading the subsequent detailed description and examples with references made to the accompanying drawings, wherein:

FIG. 1 is the system architecture of a flash memory according to an embodiment of the invention.

FIG. 2 is a schematic diagram illustrating interfaces to storage units of a flash memory according to an embodiment of the invention.

FIG. 3 is a schematic diagram depicting connections between one access sub-interface and multiple storage sub-units according to an embodiment of the invention.

FIG. 4 is the sectional diagram of a flash memory according to an embodiment of the invention.

FIG. 5 is a flowchart illustrating a method for wire bonding and testing according to an embodiment of the invention.

FIG. 6A is a schematic diagram of a substrate according to some implementations.

FIG. 6B is a schematic diagram of a substrate according to an embodiment of the invention.

FIG. 7 is a schematic diagram illustrating the connecting of a semi-finished flash-memory product to the wire-bonding equipment according to some implementations.

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

The present invention will be described with respect to particular embodiments and with reference to certain drawings, but the invention is not limited thereto and is only limited by the claims. Furthermore, It should be understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

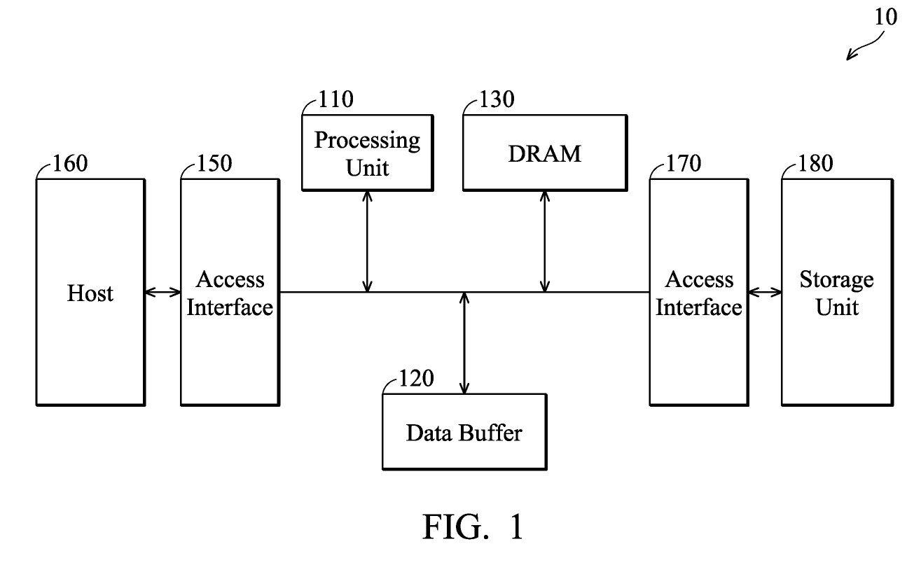

FIG. 1 is the system architecture of a flash memory according to an embodiment of the invention. The system architecture 10 of the flash memory contains a processing unit 110 being configured to write data into a designated address of a storage unit 180, and read data from a designated address thereof. Specifically, the processing unit 110 writes data into a designated address of the storage unit 180 through an access interface 170 and reads data from a designated address thereof through the same interface 170. The system architecture 10 uses several electrical signals for coordinating commands and data transfer between the processing unit 110 and the storage unit 180, including data lines, a clock signal and control lines. The data lines are employed to transfer commands, addresses and data to be written and read. The control lines are utilized to issue control signals, such as CE (Chip Enable), ALE (Address Latch Enable), CLE (Command Latch Enable), WE (Write Enable), etc. The access interface 170 may communicate with the storage unit 180 using a SDR (Single Data Rate) protocol or a DDR (Double Data Rate) protocol, such as ONFI (open NAND flash interface), DDR toggle, or others. The processing unit 110 may communicate with a host 160 through an access interface 150 using a standard protocol, such as USB (Universal Serial Bus), ATA (Advanced Technology Attachment), SATA (Serial ATA), PCI-E (Peripheral Component Interconnect Express), NVMe (Non-Volatile Memory Express), Open-Channel SSD (Solid State Disk) or others.

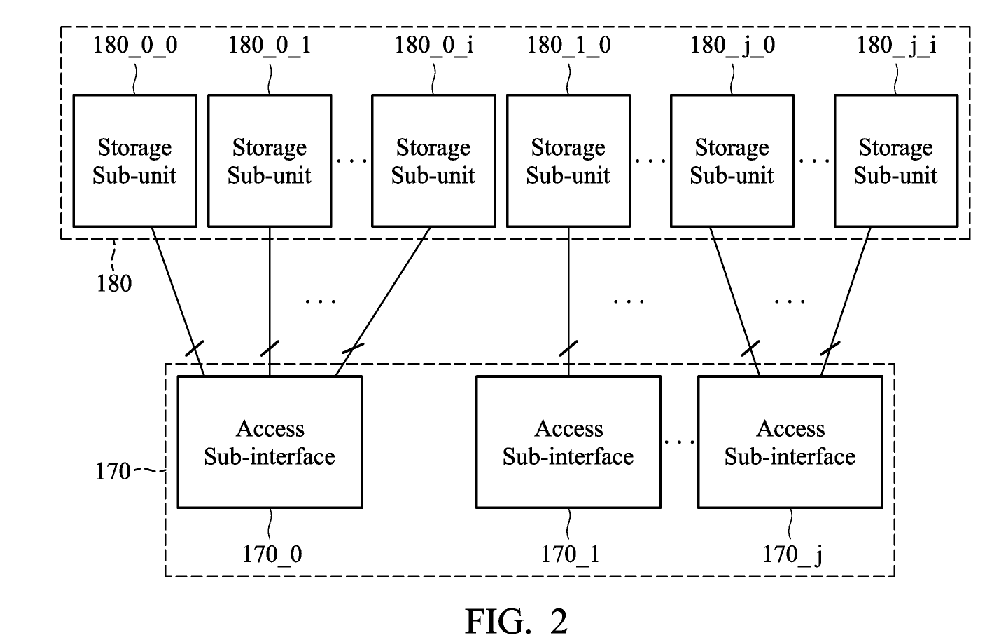

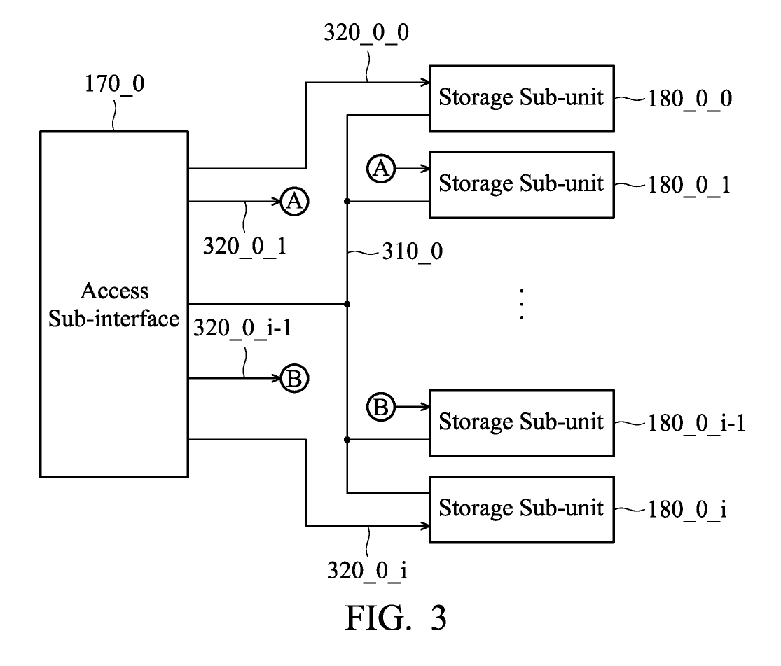

The storage unit 180 may contain multiple storage sub-units and one or more storage sub-units may be practiced in a single die and use an access sub-interface to communicate with the processing unit 110. FIG. 2 is a schematic diagram illustrating interfaces to storage units of a flash memory according to an embodiment of the invention. The flash memory 10 may contain j+1 access sub-interfaces 170_0 to 170_j, where the access sub-interfaces may be referred to as channels, and each access sub-interface connects to i+1 storage sub-units. That is, i+1 storage sub-units may share the same access sub-interface. For example, assume that the flash memory 10 contains 4 channels (j=3) and each channel connects to 4 storage sub-units (i=3): The flash memory 10 has 16 storage sub-units 180_0_0 to 180_j_i in total. The control unit 110 may direct one of the access sub-interfaces 170_0 to 170_j to read data from the designated storage sub-unit. Each storage sub-unit has an independent CE control signal. That is, it is required to enable a corresponding CE control signal when attempting to perform data read from a designated storage sub-unit via an associated access sub-interface. It is apparent that any number of channels may be provided in the flash memory 10, and each channel may be associated with any number of storage sub-units, and the invention should not be limited thereto. FIG. 3 is a schematic diagram depicting connections between one access sub-interface and multiple storage sub-units according to an embodiment of the invention. The processing unit 110, through the access sub-interface 170_0, may use independent CE control signals 320_0_0 to 320_0_i to select one of the connected storage sub-units 180_0_0 and 180_0_i, and then read data from the designated location of the selected storage sub-unit via the shared data line 310_0. The system architecture 10 of the flash memory may include a data buffer 120 for temporarily storing data received from the host 160 and to be programmed into the storage unit 180 via the access interface 170, and data received from the storage unit 180 and to be clocked out to the host 160 via the access interface 150. The system architecture 10 of the flash memory may include a DRAM (Dynamic Random Access Memory) for storing data, such as variables, data tables, etc., required during data access.

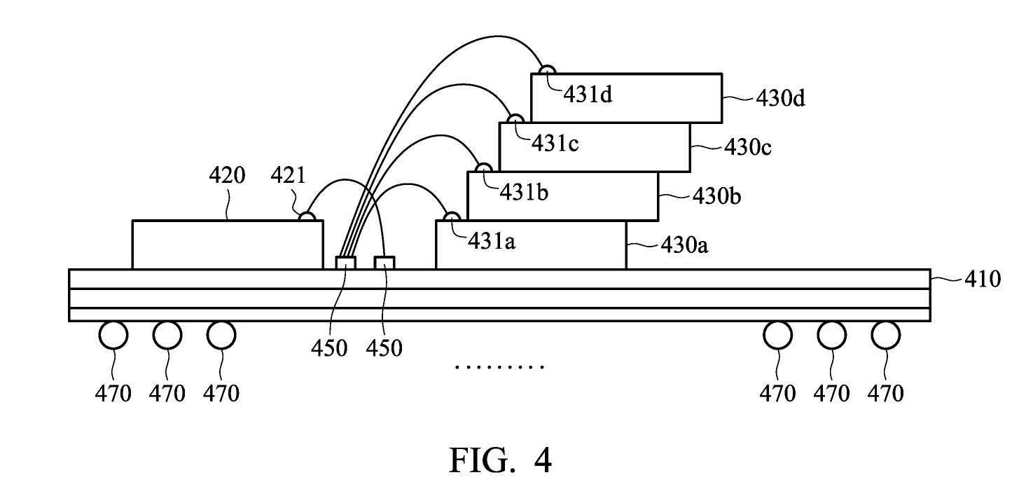

FIG. 4 is the sectional diagram of a flash memory according to an embodiment of the invention. A flash memory may contain a substrate 410 and multiple dies 420 and 430a to 430d. The substrate may contain multiple layers, the upper surface of the top layer has multiple exposed fingers 450 and the lower surface of the bottom layer has multiple exposed solder balls 470. The die 420 contains ICs (Integrated Circuits) of a controller, in which at least the processing unit 110, the data buffer 120, the DRAM 130, and the access interfaces 150 and 170 are implemented. Multiple pads are exposed and disposed on the die 420 and each pad is connected to one of the fingers 450 of the substrate 410 by a wire. The dies 430a to 430d contain ICs of storage sub-units 180_0_0 to 180_0_3, respectively, and are stacked on the substrate 410. The dies 430a to 430d may be referred to as the first- to forth-layer die from the bottom to the top. Multiple exposed pads 431a are exposed and disposed on the die 430a, multiple pads 431b are exposed and disposed on the die 430b, multiple pads 431c are exposed and disposed on the die 430c, and multiple pads 431d are exposed and disposed on the die 430d. Wire-bonding equipment connects each pad to one of the fingers 450 by a wire.

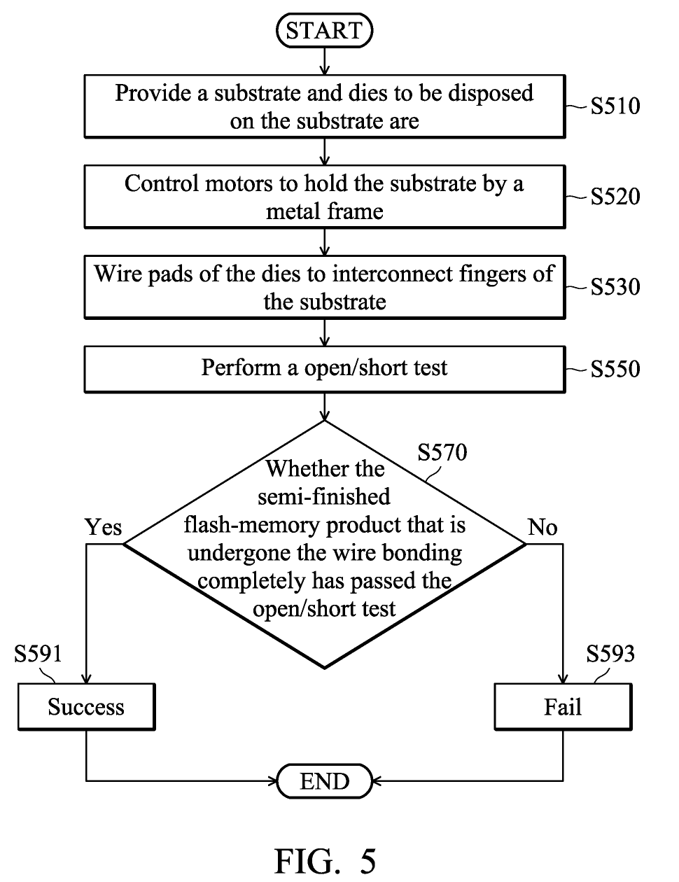

FIG. 5 is a flowchart illustrating a method for wire bonding and testing according to an embodiment of the invention. The method is performed by wire-bonding equipment. First, a substrate and dies to be disposed on the substrate are provided (step S510), one or more motors are controlled to hold the substrate by a metal frame (step S520), pads of the dies are wired to interconnect fingers of the substrate so as to manufacture a semi-finished flash-memory product (step S530), and a open/short test is performed to the semi-finished flash-memory product (step S550). Next, the wire-boding equipment determines whether the semi-finished flash-memory product that is undergone the wire bonding completely has passed the open/short test (step S570). If so (the “Yes” path of step S570), then the wire bonding is successful (step S591). Otherwise (the “No” path of step S580), the wire bonding is failed (step S593).

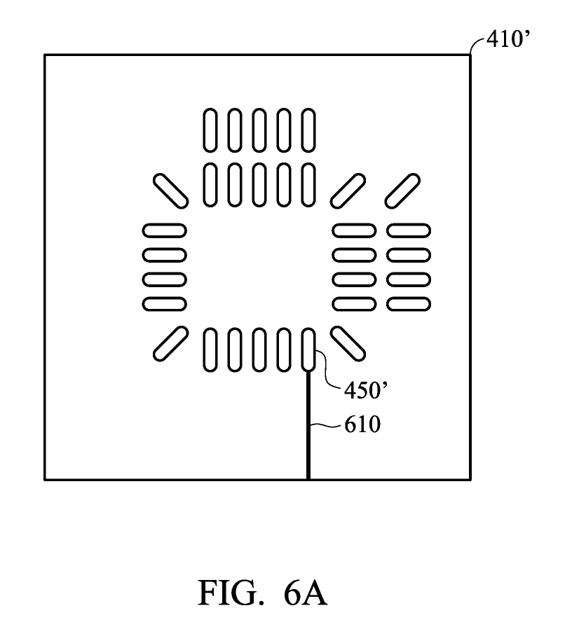

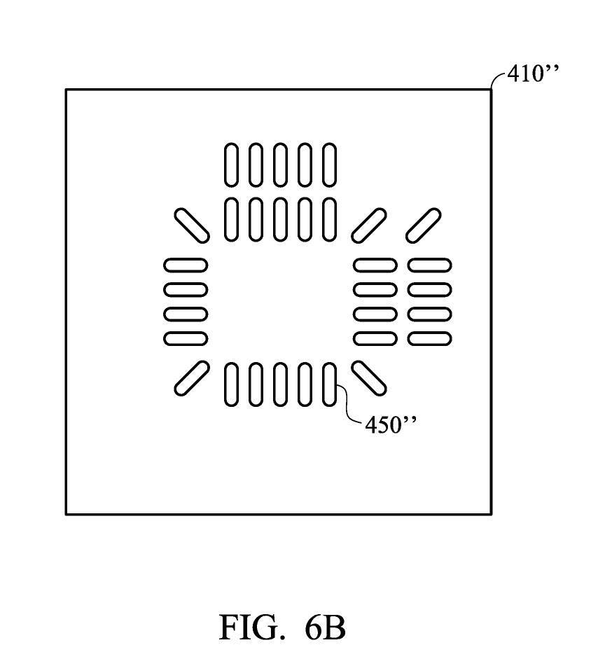

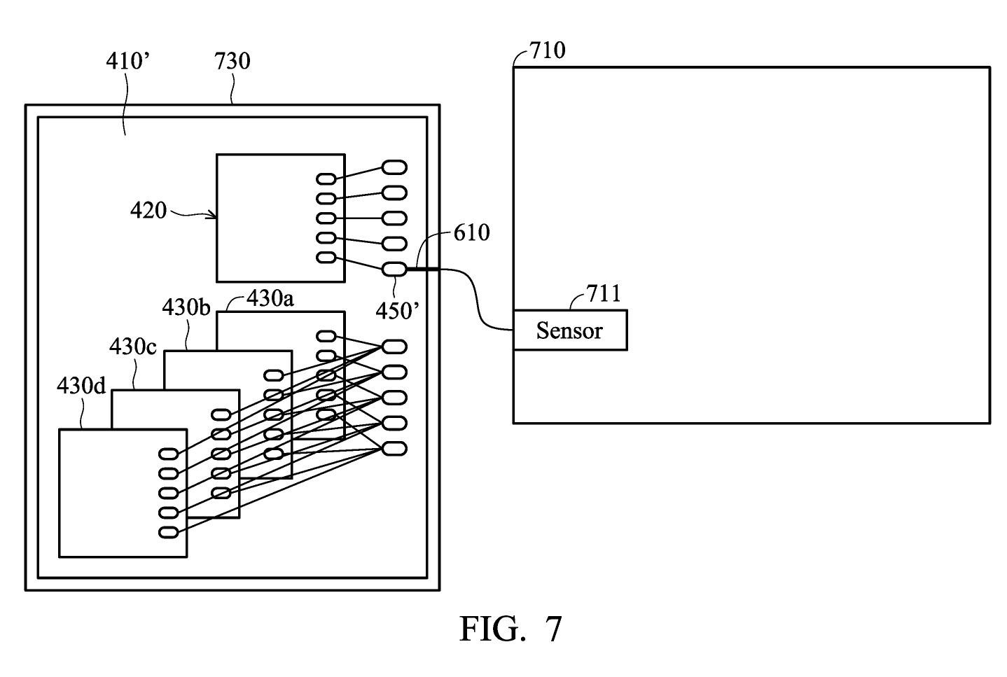

FIG. 6A is a schematic diagram of a substrate according to some implementations. In some implementations, at least one metal line 610 presented on a substrate 410′ being provided in step 5510 is connected between a finger 450′ and an edge of the substrate 410′. The metal line 610 may be formed by an electroplating process or a non-plating process. FIG. 7 is a schematic diagram illustrating the connecting of a semi-finished flash-memory product to the wire-bonding equipment according to some implementations. During the wire bonding, a metal frame is used to clamp the edges of the substrate 410′ and a sensor 711 of the wire-bonding equipment 710 is connected to the metal frame 730. When the metal frame clamps the edges of the substrate 410′, the metal frame 730 is the ground of components of the dies 420 and 430a-430d, thereby enabling the wire-bonding equipment 710, when bonding each wire in step S530, receives an electrical signal through the sensor 411 and performs a non-sticking test. Therefore, the wire-bonding equipment 710 knows whether electrical connections between the die and the substrate 410′, or any of the dies 430a to 430d and the substrate 410′ have satisfied the requirements. Charges generated during the wire bonding are flowed in conductive paths. However, after over hundreds times of the wire bonding, some charges may be flowed and accumulated in some components of the dies. ESD (electrostatic discharge) fail happens to damage the controller of the die 420 or the storage sub-units of one of the dies 430a to 430d.

To avoid the above ESD fail, the embodiments of the invention provide a new substrate. FIG. 6B is a schematic diagram of a substrate according to an embodiment of the invention. Refer to FIG. 7. The substrate held by the metal frame 730 is replaced with a substrate 410″ as shown in FIG. 6B and no metal line is formed on the substrate 410″ to connect between the fingers 450″ and the edges of the substrate 410″. When the metal frame 730 clamps the edges of the substrate 410″ in step S520, all fingers 450″ are floating from the metal frame 730, so that the metal frame 730 does not become a ground of the ICs of the controller and the storage sub-units. When all fingers 450″ are floating from the metal frame 730, there is no conductive path and charges generated during the wire bonding cannot move, so that the charges are not accumulated in a specific component of a die to induce ESD fail. To conform to the provided substrate 410″, the wire-bonding equipment 710, when bonding each wire in step S530, does not perform a non-sticking test. After the wire bonding, the open/short test performed in step S570 verifies whether all pins corresponding to the solder balls 470 of the flash memory are correctly connected to the internal circuits of the flash memory and whether a short circuit is formed between pins or between one pin and the power/ground pin. The charges generated in the wire bonding flow to the outside of the semi-product of the flash memory along multiple conductive paths through the solder balls 470 when the open/short test is performed in step S550. Although the embodiment describes one substrate in FIG. 6, those skilled in the art may realize that one metal frame holds multiple uncut substrates to perform the wire bonding for multiple flash memories and the invention should not be limited thereto.

Although the embodiment has been described as having specific elements in FIGS. 1 to 4, it should be noted that additional elements may be included to achieve better performance without departing from the spirit of the invention. While the process flow described in FIG. 5 includes a number of operations that appear to occur in a specific order, it should be apparent that these processes can include more or fewer operations, which can be executed serially or in parallel (e.g., using parallel processors or a multi-threading environment).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for wire bonding and testing, performed by wire-bonding equipment, comprising:
providing a substrate and a plurality of dies, wherein the substrate comprises a plurality of exposed fingers and each die comprises a plurality of exposed pads;
controlling a motor to hold the substrate by a metal frame, wherein all the exposed fingers are floating from the metal frame to avoid ESD (electrostatic discharge) fail; and
performing a wire bonding to make interconnections between the pads on the dies and the fingers on the substrate to fabricate a semi-finished flash-memory product.

2. The method of claim 1, wherein the step of controlling the motor to hold the substrate by the metal frame comprises:
controlling the motor to enable the metal frame to clamp edges of the substrate.

3. The method of claim 2, wherein no metal line is formed on the substrate to connect one of the exposed fingers to an edge of the substrate.

4. The method of claim 1, wherein the dies comprise ICs (Integrated Circuits) of a plurality of storage sub-units.

5. The method of claim 4, wherein the dies comprising ICs of the storage sub-units are stacked on the substrate.

6. The method of claim 1, wherein a non-sticking test is not performed in the step of performing the wire bonding.

7. The method of claim 1, comprising:
after the wire bonding, performing an open/short test to verify whether all pins corresponding to a plurality of solder balls of the flash memory are correctly connected to internal circuits of the flash memory.

8. The method of claim 7, wherein charges generated in the wire bonding flow to outside of the semi-product of the flash memory along a plurality of conductive paths through the solder balls.

9. A flash memory, comprising:
a substrate, comprising a plurality of exposed fingers, in which no metal line is formed to connect one of the exposed fingers to an edge of the substrate to avoid ESD (electrostatic discharge) fail when a wire bonding is performed;
a first die, disposed on the substrate, wherein the first die comprises ICs (Integrated Circuits) of a controller, and a plurality of exposed pads; and
a plurality of second dies, disposed on the substrate, wherein each second die comprises ICs of a storage sub-unit, and a plurality of exposed pads.

10. The flash memory of claim 9, wherein all the exposed fingers are floating from a metal frame for holding the substrate when the wire bonding is performed, so that the metal frame does not become a ground of the IC of the controller and the storage sub-units.

11. The flash memory of claim 9, wherein the second dies are stacked on the substrate.
